(19) United States
(12) Patent Application Publication
(10) Pub. No.: US 2002/0058345 A1
(43) Pub. Date: May 16, 2002

(54) Apparatus and method for removing an organic material from a semiconductor device

(76) Inventors: Anne Kurtenbach, Dresden (DE); Bernd Stottko, Dresden (DE); Torsten Schneider, Ottendorf-Okrilla (DE); Eckhard Marx, Radeburg (DE)

Correspondence Address: LERNER AND GREENBERG, P.A., Post Office Box 2480, Hollywood, FL, 33022-2480, US

(21) Appl. No.: 09/923,701

(22) Filed: Aug. 6, 2001

(30) Foreign Application Priority Data
Aug. 4, 2000 (EP) 00116886.3

(51) Int. Cl. H01L 21/00; C23C 16/00; C23F 1/02

(52) U.S. Cl. 438/8; 156/345.24; 156/345.26; 118/712

(57) ABSTRACT

An apparatus and a method for removing an organic material from a semiconductor device are provided. The apparatus has a reactor for enclosing at least one semiconductor device with deposited organic material and for enclosing a fluid having ingredients for removing the organic material. An optical sensor system is placed in such a manner that an emitted optical radiation is transmitted through the fluid. The optical sensor system is connected to a control device, which controls the insertion of at least one of the ingredients according to the detected intensity of the optical radiation transmitted through the fluid. The invention allows for optimization of the amount of at least one of the ingredients used in the process.

### BACKGROUND OF THE INVENTION

### FIELD OF THE INVENTION

The present invention relates to an apparatus and a method for removing an organic material from a semiconductor device, the apparatus having a reactor to receive at least one semiconductor device with deposited organic material and to receive a fluid having ingredients for removing the deposited organic material from the semiconductor device.

In the technical field of manufacturing of semiconductor devices, the semiconductor devices often are formed like disks or wafers for producing e.g. semiconductor chips. In the manufacturing of e.g. a semiconductor wafer, it is common and necessary to apply various process steps to the wafer. Especially lithographic processes are applied frequently in the process. Before applying a lithographic process, the wafer usually is deposited with at least one material layer such as photoresist material. The photoresist material contains organic material. By applying a lithographic process to the wafer, which has at least one deposited layer of photoresist material, structuring over the front side of the wafer can be performed. The structuring can be performed by etching e.g. irradiated portions of the photoresist material. The structured photoresist layer then usually serves as a mask for further etching processes.

After a final etching process, it usually becomes necessary to remove the remaining portions of the photoresist layer before the next process or process step is applied. For removing organic material such as photoresist material from a semiconductor wafer it is common to use fluid acids with ingredients such as e.g. sulphuric acid and hydrogen peroxide. For this purpose, the fluid acid is enclosed in a reactor or a fluid bath container in which at least one semiconductor wafer with a deposited layer of photoresist material is to be inserted. When removing the organic material, carbon components of the photoresist material are oxidized and formed into carbon dioxide, the hydrogen components are formed into water. For this process, the fluid acid usually is heated e.g. up to 130° C.

In such a process, the amount of used hydrogen peroxide generally depends on e.g. the type of photoresist material, the extent of the structuring and the amount of photoresist material to be removed. The latter especially depends on the number of wafers enclosed in the reactor. Thereby, especially two aspects have to be considered. It is necessary that the fluid acid contains a sufficient amount of hydrogen peroxide, so that a defined process time for removing the photoresist material can be performed and the photoresist material is converted sufficiently, so that the subsequent processing of the wafers is not affected. On the other hand, it is desirable that the amount of hydrogen peroxide is not higher than necessary. If less hydrogen peroxide is used in the process, the amount of water, which is formed during the process, can be decreased. As a consequence, the lifetime of the process fluid increases. Therefore, the time intervals in which the fluid has to be renewed become larger.

### SUMMARY OF THE INVENTION

It is accordingly an object of the invention to provide an apparatus and method for removing an organic material such as photoresist material from a semiconductor device of the above-mentioned type, which overcomes the hereinafore-mentioned disadvantages of the heretofore-known devices and method of this general type. The apparatus and methods of the invention are suitable for optimizing the amount of at least one of the ingredients of the fluid which is to be inserted into the reactor.

With the foregoing and other objects of the invention in view there is provided an apparatus, comprising a reactor for receiving at least one semiconductor device with deposited organic material and for receiving a fluid having ingredients for removing the organic material from the semiconductor device. An optical sensor system is provided for transmitting an emitted optical radiation through the fluid and receiving a transmitted optical radiation which has been transmitted through the fluid. A control device processes information about optical radiation intensity and controls an insertion of at least one of the ingredients into the fluid. The control device is connected to the optical sensor system and a de-gasifying device is provided for removing bubbles from the fluid.

In one embodiment the apparatus has a radiation source for emitting optical radiation of a single wavelength. The radiation source can be a laser device or a light emitting diode.

In another embodiment the apparatus has an optical cable for connecting the optical sensor system to the control device and the optical cable has a first optical fiber for transmitting the emitted optical radiation and a second optical fiber for transmitting the received optical radiation.

In another embodiment the apparatus has a fluid pipe system for inserting the fluid into the reactor and for removing the fluid from the reactor.

In another embodiment the fluid pipe system may have a filter for extracting particles and a heater for heating the fluid. The heater and the optical sensor system can be disposed relative to each other in such a manner that a fluid stream of the fluid through the fluid pipe system passes the heater and then the optical sensor system.

With objects of the invention in view, there is also provided a method for removing an organic material from a semiconductor device which includes providing a reactor. At least one semiconductor device with deposited organic material is inserted into the reactor. Fluid ingredients for removing the organic material from the semiconductor device are inserted into a fluid. An emitted optical radiation is transmitted towards the fluid. Transmitted optical radiation transmitted through the fluid is received. An optical radiation intensity which is not influenced by process induced bubbles is detected. The insertion of at least one of the ingredients is controlled in dependence on the detected optical radiation intensity.

In one embodiment the method includes the steps of modulating the emitted optical radiation and demodulating the transmitted optical radiation.

In another embodiment the method includes the step of detecting maximum values of the optical radiation intensity.

In another embodiment the method includes the step of inserting sulphuric acid and hydrogen peroxide into the fluid where the step of inserting the hydrogen peroxide may be controlled.

In another embodiment the method includes the step of monitoring the optical radiation intensity over a defined time period.

In another embodiment the method step of transmitting an emitted optical radiation towards the fluid is carried out by transmitting a blue light towards the fluid.

In another embodiment the method includes the step of comparing the detected optical radiation intensity with an initial radiation intensity detected before the semiconductor device is inserted into the reactor.

In another embodiment the method includes the steps of comparing a detected value of the optical radiation intensity with values of a pre-defined table on defined time stamps, and controlling the amount of one of the fluid ingredients to be inserted into the fluid in dependence on the comparison.

In another embodiment the method includes the step of detecting a minimum value of a measured optical radiation intensity curve.

In another embodiment the method step of inserting at least one semiconductor device with deposited organic material into the reactor is carried out by inserting at least one semiconductor device having at least one layer of photoresist material. The method step of inserting fluid ingredients for removing the organic material from the semiconductor device is carried out inserting fluid ingredients for removing the photoresist material from the semiconductor device.

The disclosed and claimed apparatus and method are applicable to various semiconductor devices with deposited organic material such as wafers for manufacturing of semiconductor chips. For example, the semiconductor device having a deposited layer of photoresist material. Further, various types of fluids can be used which are suitable for removing the organic material from the semiconductor device. Especially, a fluid is used having ingredients for removing photoresist material. Preferably, for removing photoresist material sulphuric acid and hydrogen peroxide are used as fluid ingredients.

With the provided apparatus and the provided method the amount of at least one of the ingredients such as hydrogen peroxide can be adapted. Furthermore, the process time for removing the organic material can be adapted to the amount of inserted organic material or the number of inserted wafers, respectively, and to different kinds of organic material or respective photoresist material.

With the optical sensor system the color of the process fluid can be measured. To this end, the optical sensor system emits optical radiation and receives transmitted optical radiation. Thereby, the optical radiation is emitted towards the fluid. The color of the process fluid can be detected by receiving the transmitted optical radiation, which is transmitted through the fluid. With this information it can be assured that only those semiconductor devices which leave the process fluid have been stripped off to a sufficient amount. If the process fluid is not clear enough this will be detected by the optical sensor system and e.g. a process alarm will occur. In particular, the process fluid is not clear if it contains portions of the removed organic material, which are unoxidized. Also, it can be detected by the optical sensor system if the amount of water in the process fluid exceeds a defined value. For example, the content of water in the process fluid is related to a decrease of the sensor signal provided by the optical sensor system. As well, a decrease of the sensor signal is related to the amount of unoxidized portions in the stripped-off organic material. Bubbles can be removed from the fluid with the degasifying measures.

Due to the sensor signal, the insertion of at least one of the ingredients such as hydrogen peroxide is controlled. The controlling of the insertion can be performed in such a manner that the consumption of the hydrogen peroxide in relation to the process time is optimized.

In a preferred embodiment, the apparatus has a radiation source for emitting optical radiation with a single wavelength. Preferably, blue light is emitted by the optical sensor system and transmitted through the fluid. Since the absorption of blue light by unoxidized portions in the stripped-off photoresist material is relatively high, a reliable detection of unoxidized organic material or respective photoresist material can be performed. For this purpose, the radiation source advantageously is a laser device or a light emitting diode.

According to another preferred embodiment, the optical sensor system is connected to the control device by means of an optical cable. By using an optical cable the control device does not need to be placed near the optical sensor system, since the optical sensor system is placed in an aggressive environment provided by the fluid acid. Advantageously, the optical cable includes a first optical fiber for transmitting the optical radiation, which is to be emitted and a second optical fiber for transmitting received optical radiation. Therefore, both the sender for emitting the optical radiation and the receiver for receiving the transmitted optical radiation can be placed in a suitable environment.

According to another embodiment, the apparatus includes a fluid pipe system for inserting the fluid into the reactor and for removing the fluid from the reactor. The optical sensor system is integrated into the fluid pipe system. Advantageously, the optical sensor system is integrated in such a manner that no influence on the circulation process of the fluid (pressure and flow rate) is exerted.

In a further advantageous embodiment, the fluid pipe system includes at least one filter for extracting particles. If heating of the fluid is necessary, the fluid pipe system also has a heater. Preferably, the heater and the optical sensor system are disposed relative to each other in such a manner that a fluid stream through the fluid pipe system passes the heater and then the optical sensor system.

To improve the measuring functionality of the apparatus and the method the optical radiation is modulated for emitting and demodulated for receiving. Therefore, it is possible to perform a measurement that is independent of outside illumination. Further, if maximum values of the received optical radiation intensity are detected within a defined time period an influence of bubbles induced by the process can be overcome by filtering of bubble-induced peaks of the sensor signal.

Other features which are considered as characteristic for the invention are set forth in the appended claims.

Although the invention is illustrated and described herein as embodied in an apparatus and method for removing an organic material from a semiconductor device, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE DRAWINGS

FIG. 1 is a block diagram of the apparatus according to the invention;

FIG. 2 is a block diagram of the optical sensor system;

FIG. 3 is a diagrammatic, cross-sectional view of a wafer; and

FIG. 4 is a graph showing a measured sensor signal in relationship to the process time.

### DESCRIPTION OF THE PREFERRED EMBODIMENTS

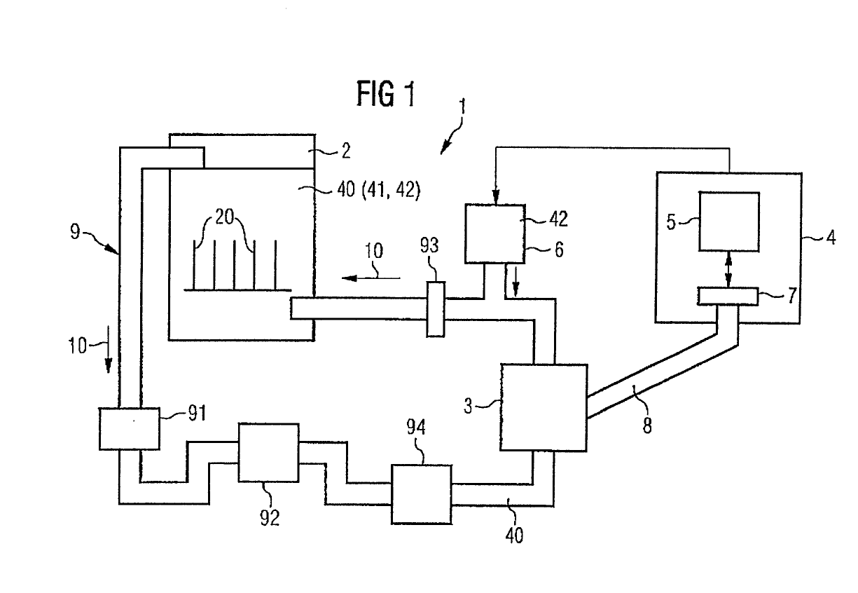

Referring now to the figures of the drawings in detail and first particularly to FIG. 1 thereof, there is seen an embodiment of the apparatus according to the invention. The apparatus 1 includes a reactor 2 for enclosing semiconductor devices 20 such as wafers. For example, the reactor 2 is suitable for enclosing a number of from 5 up to 50 wafers piled up in a suitable clamping device. The reactor 2 can be positioned on at least one side to form a tank or a bath. On the other hand it can be formed as a closed reactor with pipes connected to it. The wafers 20 have at least one deposited layer of photoresist material, which is to be removed. In the reactor 2 a fluid 40 having ingredients 41 and 42 for removing the photoresist material from the wafers 20 is also enclosed. This type of process fluid also is known as so-called piranha.

Further, the apparatus 1 includes a fluid pipe system 9 for inserting the fluid 40 into the reactor 2 and for removing the fluid 40 from the reactor 2. The fluid pipe system 9 includes a pump 91 for providing a fluid stream 10 through the fluid pipe system 9. Further, the fluid pipe system 9 has a filter 92 for extracting particles out of the fluid 40 and a de-gasifier 93 for removing bubbles from the fluid 40, each of them placed at exemplified positions. The fluid pipe system 9 has a heater 94 for heating the fluid 40 to e.g. 130° C. An optical sensor system 3 is integrated into the fluid pipe system 9. The optical sensor system 3 and the heater 94 are disposed relative to each other in such a manner that the fluid stream 10 through the fluid pipe system 9 first passes the heater 94 and then the optical sensor system 3.

The fluid 40 contains sulphuric acid 41 (H₂SO₄) and hydrogen peroxide 42 (H₂O₂) as fluid ingredients. Additionally, ozone (O₃) can be inserted as further ingredient of the fluid 40. The insertion of hydrogen peroxide 42 into the fluid pipe system 9 is controlled with a spiking pump 6. The spiking pump 6 is connected to a controlling circuit 4 including a data processing unit 5. The spiking pump 6 is controlled by the controlling circuit 4. The data processing unit 5 and respective controlling circuit 4 are connected to the optical sensor system 3 by an optical cable 8. The controlling circuit 4 includes a radiation source 7 for emitting optical radiation, which is transferred via the optical cable 8 to the optical sensor system 3. For example, the radiation source 7 can be a laser device or a light emitting diode for emitting optical radiation with a single wavelength.

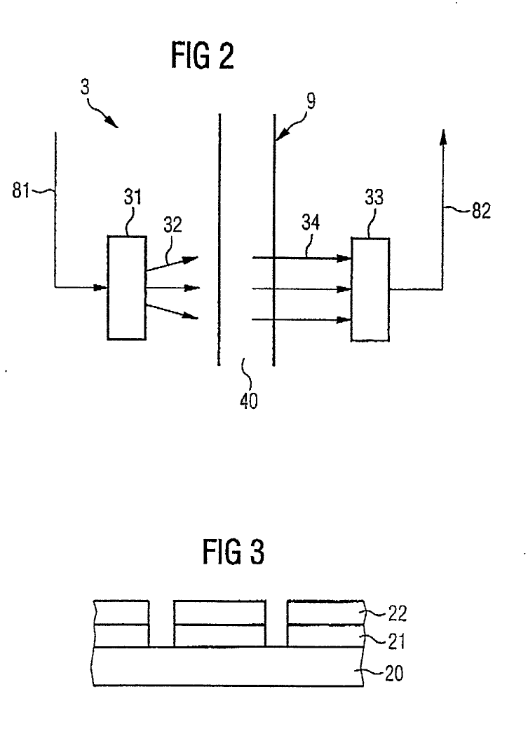

FIG. 2 shows a more detailed view of the optical sensor system 3. The pipe of the fluid pipe system 9 containing the fluid 40 is disposed in the center of the optical sensor system 3. The optical sensor system 3 has a sender 31 for emitting optical radiation 32 towards the fluid 40. The optical radiation 32 is provided by an optical fiber 81, which is part of the optical cable 8 according to FIG. 1. The radiation 32, which is to be emitted, is transmitted from the radiation source 7 via the optical fiber 81. The optical sensor system 3 further includes a receiver 33 for receiving the transmitted optical radiation. Especially, the receiver 33 is constructed for receiving the transmitted optical radiation 34, which is transmitted through the fluid 40. The received optical radiation 34 is further transmitted to the controlling circuit 4 via the optical fiber 82 which is part of the optical cable 8.

FIG. 3 diagrammatically shows a cross-sectional view of one of the wafers 20 enclosed in the reactor 2 according to FIG. 1. The wafer 20 is deposited with layers 21 and 22. Layer 22 is formed of photoresist material irradiated in a lithographic process. The photoresist layer 22 forms a mask for etching the layer 21. After the etching process, trenches are formed as shown in FIG. 3. In a following process, the remaining portions of the photoresist layer 22 have to be removed by inserting the wafer 20 into the reactor 2 according to FIG. 1.

The transmission of blue light (wavelength of about 550 nm) through the fluid 40 is measured with the optical sensor system 3. The fluid 40 changes its color by removing the photoresist material 22 from the wafer 20. When the removed photoresist material is fully oxidized, the fluid 40 is nearly as clear as at the beginning of the process. The described change of color can be measured by the optical sensor system 3. The optical radiation is modulated for emitting and demodulated for receiving in order to be independent from outside illumination. This can be performed by the data processing unit 5. If, within a defined time period, only maximum values of the received optical radiation intensity are detected, the result of the measurement is not influenced by induced bubbles, which usually lead to scattering of the transmitted radiation.

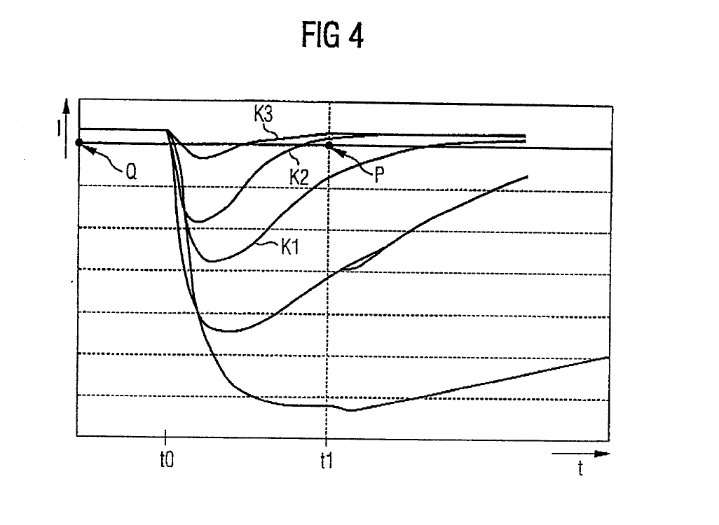

FIG. 4 shows a diagram of a measured sensor signal I in relationship to the process time t. The sensor signal I is derived from the detected optical radiation intensity measured by the optical sensor system 3. In this example, the optical radiation intensity is detected and transferred into a voltage signal. FIG. 4 shows the sensor signal I derived from the received radiation intensity. The diagram schematically shows an example of a process for removing photoresist materials deposited on five wafers 20. There are shown three curves K1 to K3, each for a different number of strokes of the spiking pump 6 pumping the hydrogen peroxide 42 into the fluid pipe system 9. The curve K1 designates the lowest number of strokes. The curve K3 designates the highest number of strokes.

The process begins with the time t0. The large decrease of each of the curves at the beginning of the process denotes the extent of the dissolution of the photoresist material. Since a relative high amount of unoxidized portions in the stripped-off photoresist material occurs at the beginning of the process, the absorption of the transmitted light through the fluid 40 is quite large. Therefore, the signal I decreases. The process of oxidation of the photoresist material can be accelerated with the inserting of hydrogen peroxide 42 into the fluid 40. This is illustrated by the different increases of the curves K1 to K3. When the curves exceed the level Q, which is a value for a minimum process fluid quality (for example 90% of the initial value of the signal I), the fluid is clear enough for inserting the next lot of wafers. The time t1 denotes the end of the process. For the curves K2 and K3, a sufficient process fluid quality for the next process is reached. The optimized number of strokes of the spiking pump 6 will be probably between the number of strokes of the curves K1 and K2 to meet exactly the point P.

For instance, an end point detection is performed. To this end, the sensor signal I is compared with the initial signal I of the clean process fluid before the wafers 20 are inserted into the reactor 2. The difference between these two signals has to be in a defined range after a certain time limit. The optical sensor system 3 can detect one wafer with deposited photoresist material entering the reactor 2. The optical sensor system 3 can detect two different states, e.g. “process fluid clean” or “process fluid not clean”. If the process time is finished and the process fluid or respective fluid is not clean, an additional amount of hydrogen peroxide and process time will be added.

In a further embodiment, a process control can be performed with the goal of reduction of the hydrogen peroxide consumption and process time. The intensity of the received optical radiation is detected and the generated sensor signal, e.g. the slope of descent of the signal which is a function of the number of coated wafers inserted into the process fluid, is compared with a pre-defined table with signals on defined time stamps. The signals are characteristic for a process fluid which is not full with wafers. The sensor signal is compared with the predefined table during the process at certain time steps. Due to the results of the comparison, the amount of hydrogen peroxide to be inserted into the fluid is controlled. This can be performed with a special control algorithm, e.g. with a PID-controller with a pre-defined target value. In a second method, the point of strongest absorption can be measured (characterized by a minimum value of the respective curve).

The optical radiation intensity or respective sensor signal is monitored over a defined time period for process cost minimization. The lifetime of the process fluid can be monitored by monitoring the sensor signal since the content of water in the fluid, which is formed during several processes, is related to the course of recovery of the process fluid after removing the photoresist material of a lot of wafers. The recovery time of the process fluid becomes larger with the ageing of the fluid. The tracking of the recovery time can be used to define the lifetime of the process fluid. As an alternative, a maximum amount of hydrogen peroxide per each of the wafers or the batches and a maximum process time period are defined. If a lot of wafers or a batch can't be processed completely in the defined time period with the defined amount of hydrogen peroxide (level Q isn't exceeded), a change of the fluid has to be made.

We claim:

1. An apparatus for removing an organic material from a semiconductor device, comprising:
a reactor for receiving at least one semiconductor device with deposited organic material and receiving a fluid having ingredients for removing the organic material from the semiconductor device;
an optical sensor system for transmitting an emitted optical radiation through the fluid and receiving a transmitted optical radiation transmitted through the fluid;
a control device for processing information about optical radiation intensity and for controlling an insertion of at least one of the ingredients into the fluid, said control device connected to said optical sensor system; and
a de-gasifying device for removing bubbles from the fluid.

2. The apparatus according to claim 1, further comprising a radiation source for emitting said emitted optical radiation, said emitted optical radiation having a single wavelength.

3. The apparatus according to claim 2, wherein said radiation source includes a laser device or a light emitting diode.

4. The apparatus according to claim 1, further comprising an optical cable for connecting said optical sensor system to the control device.

5. The apparatus according to claim 4, wherein said optical cable has a first optical fiber for transmitting said emitted optical radiation and a second optical fiber for transmitting said received optical radiation.

6. The apparatus according to claim 1, further comprising a fluid pipe system for inserting the fluid into said reactor and for removing the fluid from said reactor, said optical sensor system integrated into said fluid pipe system.

7. The apparatus according to claim 6, wherein said fluid pipe system has at least one filter for extracting particles.

8. The apparatus according to claim 6, wherein said fluid pipe system has a heater for heating the fluid.

9. The apparatus according to claim 8, wherein said heater and said optical sensor system are disposed relative to each other in such a manner that a fluid stream of the fluid through said fluid pipe system passes said heater and then said optical sensor system.

10. A method for removing an organic material from a semiconductor device, which comprises the steps:
providing a reactor;
inserting at least one semiconductor device with deposited organic material into the reactor;
inserting fluid ingredients for removing the organic material from the semiconductor device into a fluid;
transmitting an emitted optical radiation towards the fluid;
receiving transmitted optical radiation transmitted through the fluid;
detecting an optical radiation intensity not influenced by process induced bubbles; and
controlling the insertion of at least one of the ingredients in dependence on the detected optical radiation intensity.

11. The method according to claim 10, which further comprises the steps of modulating the emitted optical radiation and demodulating the transmitted optical radiation.

12. The method according to claims 10, which further comprises the step of detecting maximum values of the optical radiation intensity.

13. The method according to claim 10, which further comprises the step of inserting sulphuric acid and hydrogen peroxide into the fluid.

14. The method according to claim 13, which further comprises the step of controlling the insertion of hydrogen peroxide.

15. The method according to claim 10, which further comprises the step of monitoring the optical radiation intensity over a defined time period.

16. The method according to claim 10, wherein the step of transmitting an emitted optical radiation towards the fluid is carried out by transmitting a blue light towards the fluid.

17. The method according to claim 10, which further comprises the step of comparing the detected optical radiation intensity with an initial radiation intensity detected before the semiconductor device is inserted into the reactor.

18. The method according to claim 10, which further comprises the steps of comparing a detected value of the optical radiation intensity with values of a pre-defined table on defined time stamps, and controlling the amount of one of the fluid ingredients to be inserted into the fluid in dependence on the comparison.

19. The method according to claims 10, which further comprises the step of detecting a minimum value of a measured optical radiation intensity curve.

20. The method according to claim 10, which further comprises carrying out the step of inserting at least one semiconductor device with deposited organic material into the reactor by inserting at least one semiconductor device with photoresist material, and carrying out the step of inserting fluid ingredients for removing the organic material from the semiconductor device by inserting fluid ingredients for removing the photoresist material from the semiconductor device.

21. An apparatus for removing an organic material from a semiconductor device, comprising:
a reactor for receiving at least one semiconductor device with deposited organic material and for receiving a fluid having ingredients for removing the organic material from the semiconductor device;
an optical sensor system for receiving a transmitted optical radiation transmitted through the fluid, said transmitted optical radiation having an optical radiation intensity; and
a control device connected to said optical sensor system for processing information about said optical radiation intensity of said transmitted optical radiation, said control device controlling an insertion of at least one of the ingredients into the fluid depending on said optical radiation intensity of said transmitted optical radiation.
